(19) United States
(12) Patent Application Publication
(10) Pub. No.: US 2020/0166833 A1
(43) Pub. Date: May 28, 2020

(54) MASK BLANK, METHOD OF MANUFACTURING TRANSFER MASK, AND METHOD FOR MANUFACTURING SEMICONDUCTOR DEVICE

(71) Applicants: HOYA CORPORATION, Tokyo (JP); HOYA ELECTRONICS SINGAPORE PTE. LTD., Singapore (SG)

(72) Inventors: Masahiro HASHIMOTO, Tokyo (JP); Mariko UCHIDA, Singapore (SG)

(73) Assignees: Hoya Corporation, Tokyo (JP); Hoya Electronics Singapore PTE. Ltd., Singapore (SG)

(21) Appl. No.: 16/615,542

(22) PCT Filed: May 15, 2018
(86) PCT No.: PCT/JP2018/018707

§ 371 Date: Nov. 21, 2019

(30) Foreign Application Priority Data
May 31, 2017 (JP) 2017-107767

(51) Int. Cl. G03F 1/54; G03F 1/50; G03F 7/20; H01L 21/027

(52) U.S. Cl. CPC G03F 1/54; H01L 21/0274; G03F 7/2006; G03F 1/50

(57) ABSTRACT

A mask blank includes a light shielding film for forming a transfer pattern, provided on a transparent substrate. The light shielding film is made of a material that consists of silicon and nitrogen or that further includes one or more elements selected from a metalloid element and a non-metallic element. In an inner region of the light shielding film (excluding a vicinity region of an interface of the light shielding film with the transparent substrate and a surface layer region of the light shielding film opposite the transparent substrate), the ratio of Si₃N₄ bonds to the total number of Si₃N₄ bonds, SiₐN_{b} bonds (where a relationship b/[a+b]<4/7 is satisfied), and Si—Si bonds is 0.04 or less, and the ratio of SiₐN_{b} bonds to the total number of Si₃N₄ bonds, SiₐN_{b} bonds, and Si—Si bonds is 0.1 or more.

### CROSS REFERENCE TO RELATED APPLICATIONS

This application is a National Stage of International Application No. PCT/JP2018/018707 filed May 15, 2018, which claims priority to Japanese Patent Application No. 2017-107767 filed May 31, 2017, and the contents of which is incorporated by reference in its entirety.

### TECHNICAL FIELD

This disclosure relates to a mask blank, and a method of manufacturing a transfer mask manufactured using the mask blank. Further, this disclosure relates to a method of manufacturing a semiconductor device using the transfer mask.

### BACKGROUND ART

In a manufacturing process of a semiconductor device, a fine pattern is formed using a photolithography method. A number of transfer masks are usually used to form the fine pattern. In order to miniaturize a pattern of a semiconductor device, in addition to miniaturization of a mask pattern formed on a transfer mask, it is necessary to shorten a wavelength of an exposure light source used in photolithography. In recent years, application of an ArF excimer laser (wavelength 193 nm) is increasing as an exposure light source in the manufacture of semiconductor devices.

There are various kinds of transfer masks, among which a binary mask and a half tone phase shift mask are widely used. A conventional binary mask has generally been provided with a light shielding film pattern made of a chromium-based material on a transparent substrate, but in recent years, a binary mask in which a light shielding film is made of a transition metal silicide-based material has begun to be used. However, as disclosed in Patent Document 1, it has been found in recent years that a light shielding film of a transition metal silicide-based material has low resistance to exposure light of an ArF excimer laser (ArF exposure light) (so-called ArF light fastness). In Patent Document 1, ArF light fastness is enhanced by applying a material in which carbon or hydrogen is contained in transition metal silicide to a light shielding film.

On the other hand, Patent Document 2 discloses a phase shift mask including an SiNx phase shift film. Patent Document 3 describes that an SiNx phase shift film was confirmed as having high ArF light fastness. On the other hand, Patent Document 4 discloses a defect repairing technique where xenon difluoride (XeF₂) gas is supplied to a black defect portion of a light shielding film while irradiating the portion with an electron beam to etch and remove the black defect portion (defect repair by irradiating charged particles such as an electron beam as above is hereafter simply referred to as EB defect repair).

### PRIOR ART PUBLICATIONS

### Patent Documents

### [Patent Document 1]

International Publication WO 2010/092899

### [Patent Document 2]

Japanese Patent Application Publication H08-220731

### [Patent Document 3]

Japanese Patent Application Publication 2014-137388

### [Patent Document 4]

PCT Application Japanese Translation Publication 2004-537758

### SUMMARY OF THE DISCLOSURE

### Problems to be Solved by the Disclosure

A phase shift film made of materials containing silicon and nitrogen that do not contain transition metals (hereinafter referred to as SiN-based materials) as disclosed in Patent Document 2 and Patent Document 3 is already known as having high Arf light fastness. The present inventors attempted to apply this SiN-based material to a light shielding film of a binary mask, and the ArF light fastness of the light shielding film could be enhanced. However, when an EB defect repair was performed on a black defect portion found in the pattern of the light shielding film of the SiN-based material, it was found that two major problems occurred.

One major problem is that when an EB defect repair was performed to remove a black defect portion of a light shielding film, a surface of a transparent substrate in the region where the black defect existed is extremely roughened (the surface roughness is significantly deteriorated). A region of a surface of a binary mask which is roughened after the EB defect repair is a region which becomes a light transmitting portion for transmitting ArF exposure light. When the surface roughness of the substrate of the light transmitting portion is significantly deteriorated, it is likely to cause reduction in transmittance of ArF exposure light, occurrence of diffused reflection, etc. Such a binary mask causes a significant reduction in transfer accuracy when the binary mask is placed on a mask stage of an exposure apparatus and used for exposure transfer.

Another major problem is that when an EB defect repair is performed to remove a black defect portion of a light shielding film, a light shielding film pattern existing around the black defect portion is etched from the side wall (this phenomenon is called spontaneous etching). When a spontaneous etching occurs, the light shielding film pattern becomes much thinner than the width before the EB defect repair. In the case of a light shielding film pattern having a thin width at the stage before the EB defect repair, there is a risk of falling off or loss of the pattern. Such a binary mask having a light shielding film pattern where a spontaneous etching is likely to occur causes a significant reduction in transfer accuracy when the binary mask is placed on a mask stage of an exposure apparatus and used for exposure transfer.

Thus, this disclosure was made to solve the conventional problems, and an aspect of this disclosure is to provide a mask blank which, when an EB defect repair was performed on a black defect portion of a light shielding film made of an SiN-based material, generation of a surface roughness of a transparent substrate is suppressed, and generation of a spontaneous etching in the light shielding film pattern is also suppressed. Further, an aspect of this disclosure is to provide a method of manufacturing a transfer mask using this mask blank. Moreover, an aspect of this disclosure is to provide a method of manufacturing a semiconductor device using this transfer mask.

### Means for Solving the Problem

For solving the above problem, this disclosure includes the following configurations.

### (Configuration 1)

A mask blank including:

a transparent substrate; and

a light shielding film for forming a transfer pattern on the transparent substrate,

where:

the light shielding film is made of a material consisting of silicon and nitrogen, or a material consisting of silicon, nitrogen, and one or more elements selected from a metalloid element and a non-metallic element,

an inner region of the light shielding film is a region excluding a vicinity region of an interface of the light shielding film with the transparent substrate and a surface layer region of the light shielding film opposite the transparent substrate,

a ratio calculated by dividing a number of Si₃N₄ bonds being present in the inner region by a total number of Si₃N₄ bonds, SiₐN_{b} bonds (where a relationship b/[a+b]<4/7 is satisfied), and Si—Si bonds being present in the inner region is 0.04 or less, and

a ratio calculated by dividing a number of SiₐN_{b} bonds being present in the inner region by a total number of Si₃N₄ bonds, SiₐN_{b} bonds, and Si—Si bonds being present in the inner region is 0.1 or more.

### (Configuration 2)

The mask blank according to Configuration 1, in which a region of the light shielding film excluding the surface layer region has oxygen content of 10 atom % or less.

### (Configuration 3)

The mask blank according to Configuration 1 or 2, in which the surface layer region is a region ranging from a surface of the light shielding film opposite the transparent substrate up to a depth of 5 nm toward the transparent substrate.

### (Configuration 4)

The mask blank according to any one of Configurations 1 to 3, in which the vicinity region is a region ranging from an interface with the transparent substrate up to a depth of 5 nm toward the surface layer region.

### (Configuration 5)

The mask blank according to any one of Configurations 1 to 4, in which the light shielding film is made of a material consisting of silicon, nitrogen, and a non-metallic element.

### (Configuration 6)

The mask blank according to any one of Configurations 1 to 5, in which the surface layer region has more oxygen content than a region of the light shielding film excluding the surface layer region.

### (Configuration 7)

The mask blank according to any one of Configurations 1 to 6, in which the light shielding film has an optical density to an exposure light of an ArF excimer laser of 2.5 or more.

### (Configuration 8)

The mask blank according to any one of Configurations 1 to 7, in which the light shielding film is provided in contact with a main surface of the transparent substrate.

### (Configuration 9)

A method of manufacturing a transfer mask using the mask blank according to any one of Configurations 1 to 8, including the step of forming a transfer pattern in the light shielding film by dry etching.

### (Configuration 10)

A method of manufacturing a semiconductor device including the step of exposure-transferring a transfer pattern in a resist film on a semiconductor substrate using the transfer mask manufactured by the method of manufacturing a transfer mask according to Configuration 9.

### Effect of the Disclosure

The mask blank of this disclosure can suppress generation of surface roughness of a transparent substrate, and also suppress generation of a spontaneous etching in the pattern of a light shielding film pattern when an EB defect repair was performed on a black defect portion of a light shielding film pattern made of an SiN-based material.

The method of manufacturing a transfer mask of this disclosure can suppress generation of surface roughness of a transparent substrate, and also suppress generation of a spontaneous etching in a light shielding film pattern in vicinity of a black defect portion when an EB defect repair was performed on a black defect portion of a light shielding film pattern during manufacture of the transfer mask.

Therefore, the transfer mask manufactured by the method of manufacturing the transfer mask of this disclosure results in a transfer mask having high transfer precision.

### BRIEF DESCRIPTION OF THE DRAWINGS

FIG. 1 shows a result of an X-ray photoelectron spectroscopy on an inner region of a light shielding film of a mask blank according to Example 1 of this disclosure.

FIG. 2 shows a result of an X-ray photoelectron spectroscopy on an inner region of a light shielding film of a mask blank according to Example 3 of this disclosure.

FIG. 3 shows a result of an X-ray photoelectron spectroscopy on an inner region of a light shielding film of a mask blank according to Example 5 of this disclosure.

FIG. 4 shows a result of an X-ray photoelectron spectroscopy on an inner region of a light shielding film of a mask blank according to Comparative Example 1 of this disclosure.

FIG. 5 is a cross-sectional view showing a configuration of a mask blank of an embodiment of this disclosure.

FIG. 6A-6F are cross-sectional views showing the manufacturing steps of a transfer mask of an embodiment of this disclosure.

### EMBODIMENTS FOR CARRYING OUT THE DISCLOSURE

First, the sequence that derived the completion of this disclosure is described.

The present inventors diligently studied a configuration of a light shielding film where generation of surface roughness of a transparent substrate is suppressed, and also generation of a spontaneous etching in a light shielding film pattern is suppressed when an EB defect repair was performed on a black defect portion of a light shielding film made of an SiN-based material. First, when an EB defect repair was performed on a pattern of a phase shift film made of an SiN-based material, there was substantially no problem regarding a spontaneous etching, although there was a problem in a significantly slow repair rate.

XeF₂ gas used in an EB defect repair is known as non-excited etching gas when carrying out an isotropic etching on a silicon-based material. The etching is carried out by the processes of surface adsorption of non-excited XeF₂ gas on a silicon-based material, separation into Xe and F, generation of higher-order fluoride of silicon, and volatilization. In an EB defect repair on a thin film pattern of a silicon-based material, non-excited fluorine-based gas such as XeF₂ gas is supplied to a black defect portion of the thin film pattern, the fluorine-based gas is adsorbed to the surface of the black defect portion, and an electron beam is irradiated on the black defect portion. As a result, the silicon in the black defect portion is excited to accelerate the binding with fluorine, and is volatilized as a higher-order fluoride of silicon much faster than without irradiation of the electron beam. Since it is difficult to prevent fluorine-based gas from being adsorbed to the thin film pattern around the black defect portion, the thin film pattern around the black defect portion is also etched during an EB defect repair. When etching silicon bound to nitrogen, it is necessary to break the bond between silicon and nitrogen in order for fluorine in XeF₂ gas to bind to silicon to form a higher order fluoride of silicon. Since silicon is excited in the black defect portion irradiated with the electron beam, the bond with nitrogen is broken, and is bound to fluorine to be easily volatilized. On the other hand, silicon unbound to other elements can be regarded as in the state of being easily bound to fluorine. Therefore, silicon unbound to other elements tends to bind to fluorine and is easily volatilized even in an unexcited state without being irradiated with electron beams, or even in a light shielding film pattern around a black defect portion which is slightly affected by irradiation of electron beams. This is assumed as the mechanism of generation of a spontaneous etching.

Since a refractive index n of a silicon film with respect to an ArF exposure light is considerably small and an extinction coefficient k is large, a silicon film is not suitable as a material of a phase shift film. As a material of a phase shift film, among SiN-based materials, an SiN material containing a large amount of nitrogen to increase the refractive index n and decrease the extinction coefficient k is suitable. A phase shift film made of such an SiN-based material can be considered as having high ratio of silicon in the film bound to nitrogen, and ratio of silicon unbound to other elements is significantly low. Therefore, it can be considered that in a phase shift film made of such an SiN-based material, there was substantially no problem regarding a spontaneous etching upon an EB defect repair. On the other hand, a light shielding film of a binary mask is desired to have high light shielding performance to an Arf exposure light, namely, having a predetermined degree or more optical density (OD: Optical Density) while having less thickness. Therefore, the material of the light shielding film is desired to have a large extinction coefficient k. Due to the above reasons, the SiN-based material used in a light shielding film has significantly low nitrogen content compared to an SiN-based material used in a phase shift film. A light shielding film made of such an SiN-based material can be considered as having low ratio of silicon in the film bound to nitrogen, and having high ratio of silicon unbound to other elements. Therefore, it can be considered that in a light shielding film made of an SiN-based material, a problem regarding a spontaneous etching upon an EB defect repair is likely to occur.

Next, the present inventors studied increasing nitrogen content in an SiN-based material forming a light shielding film. When nitrogen content is significantly increased as in the SiN-based material of a phase shift film, an extinction coefficient k will become significantly low, which makes it necessary to significantly increase the thickness of the light shielding film, and repair rate upon an EB defect repair decreases. Considering the above, an EB defect repair was attempted with a light shielding film of an SiN-based material having a certain increase in nitrogen content formed on a transparent substrate. As a result, the light shielding film had sufficiently high repair rate in the black defect portion, and generation of a spontaneous etching was suppressed. However, a surface of the transparent substrate after the repair was conspicuously roughened. Repair rate of the black defect portion of the light shielding film being sufficiently large means that etching selectivity between the transparent substrate is sufficiently high, and there should have been no conspicuous roughening on the surface of the transparent substrate.

As a result of further diligent study, the present inventors found out that as a presence ratio of Si₃N₄ bond in an SiN-based material forming a light shielding film becomes greater, the surface roughness of a transparent substrate upon an EB defect repair becomes conspicuous. The SiN-based material is considered as mainly containing Si—Si bond that is unbound to elements other than silicon, Si₃N₄ bond that is in stoichiometrically stable binding condition, and SiₐN_{b} bond (provided that b/[a+b]<4/7; same hereinafter) that is in relatively unstable binding condition. Since binding energy of silicon and nitrogen is particularly strong in Si₃N₄ bond, it is difficult to break the bond between silicon and nitrogen to produce high-order fluoride bound to fluorine when an electron beam was irradiated to excite silicon. Further, since an SiN-based material forming a light shielding film has less nitrogen content compared to an SiN-based material forming a phase shift film, a presence ratio of Si₃N₄ bonds in the material tends to be low.

Considering the above, the present inventors set up the following hypothesis. Namely, in the case where a presence ratio of Si₃N₄ bonds in a film such as a light shielding film is low, distribution of Si₃N₄ bonds in planar view of a light shielding film (black defect portion) is considered as sparse (uneven). When an electron beam is irradiated from above and an EB defect repair is performed on a black defect portion of such a light shielding film, silicon in Si—Si bonds and SiₐN_{b} bonds binds to fluoride at an early stage and volatilizes. However, Si₃N₄ bonds require a great amount of energy to break the bond between silicon and nitrogen so that it takes time until silicon binds to fluoride and volatilizes. Accordingly, a significant difference generates in planar view in a removal amount of the black defect portion in a film thickness direction. Continuing the EB defect repair with such differences in the removal amount in planar view occurring in various locations in the film thickness direction will result in, in the black defect portion to which an electron beam is irradiated, formation of a region where an EB defect repair reaches a transparent substrate at an early stage and a surface of the transparent substrate is exposed, and a region where the EB defect repair does not reach up to the transparent substrate and the black defect portion still remains on the surface of the transparent substrate. Since it is technically difficult to irradiate an electron beam only on the region where the black defect portion remains, the region where the surface of the transparent substrate is exposed is also continuously irradiated with the electron beam during continuation of the EB defect repair for removing the region where the black defect portion remains. Since the transparent substrate is slightly etched to an EB defect repair, the surface of the transparent substrate is roughened until the EB defect repair is completed.

On the other hand, since a phase shift film of an SiN-based material has a large amount of nitrogen content, a presence ratio of Si₃N₄ bonds in the film is relatively high. Therefore, while a repair rate upon an EB defect repair significantly becomes slow, the distribution of Si₃N₄ bonds in planar view of the phase shift film (black defect portion) is relatively even and hardly becomes sparse. Thus, the problem of surface roughness of the transparent substrate is considered as unlikely to occur.

A diligent study was made based on the hypothesis. As a result, the inventors found out that when an EB defect repair was performed on a black defect portion of a light shielding film with a ratio of an amount of Si₃N₄ bonds being present in an SiN-based material forming the light shielding film, divided by a total number of Si₃N₄ bonds, SiₐN_{b} bonds, and Si—Si bonds being present is a certain value or less, the surface roughness of the transparent substrate of the region where the black defect portion existed can be reduced to a degree where there is substantially no influence upon exposure transfer when used as a transfer mask. In a light shielding film of an SiN-based material, oxidization of a surface layer region exposed to the atmosphere (surface layer region opposite the transparent substrate) is inevitable. This oxidization of the surface layer, however, advances substantially evenly in planar view, and silicon bound to oxygen requires more energy to break the bond to bind to fluoride compared to silicon bound to nitrogen. Due to the above, the unevenness of the Si₃N₄ bonds of the oxidized surface layer region in planar view has less influence on unevenness of removal amount in planar view upon an EB defect repair. Moreover, while the vicinity region of an interface with the transparent substrate is inferred as configured similarly as the inner region excluding the vicinity region and the surface layer region, since an influence of the composition of the transparent substrate is inevitable when composition analysis such as RBS (Rutherford Back-Scattering Spectrometry) and XPS (X-ray Photoelectron Spectroscopy) is performed, it is difficult to specify the composition and the number of bonds being present. Further, even if the distribution of Si₃N₄ bonds was uneven in the vicinity region, there is less influence due to small ratio of the entire film thickness of the light shielding film. Therefore, the surface roughness of the transparent substrate in an EB defect repair can be considered as significantly suppressed when the ratio calculated by dividing the number of Si₃N₄ bonds being present in the inner region excluding the vicinity region of an interface of the transparent substrate and the light shielding film and the surface layer region opposite the transparent substrate by a total number of Si₃N₄ bonds, SiₐN_{b} bonds (where a relationship b/[a+b]<4/7 is satisfied), and Si—Si bonds being present in the inner region is 0.04 or less.

Furthermore, the inventors found out that, when the ratio calculated by dividing the number of SiₐN_{b} bonds being present in the inner region of the light shielding film by a total number of Si₃N₄ bonds, SiₐN_{b} bonds, and Si—Si bonds being present in the inner region is 0.1 or more, there will be a certain ratio or more of silicon bound to nitrogen in the inner region of the light shielding film, and when an EB defect repair was performed on the black defect portion of the light shielding film, occurrence of a spontaneous etching on a pattern side wall of the light shielding film around the black defect portion can be significantly suppressed.

This disclosure has been completed as a result of the diligent studies described above.

Next, the embodiments of this disclosure are described.

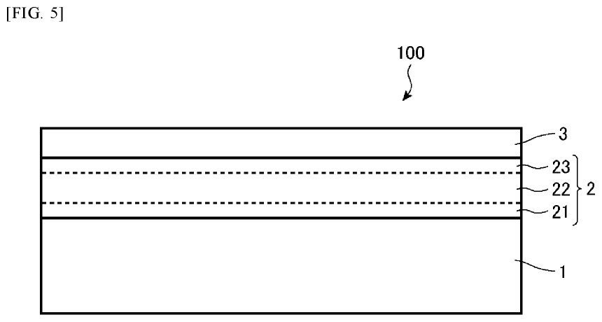

FIG. 5 is a cross-sectional view showing a configuration of a mask blank 100 of an embodiment of this disclosure.

The mask blank 100 of FIG. 5 has a configuration where a light shielding film 2 and a hard mask film 3 are stacked in this order on a transparent substrate 1.

### [[Transparent Substrate]]

The transparent substrate 1 is made from a material containing silicon and oxygen, and can be made from glass materials such as synthetic quartz glass, quartz glass, aluminosilicate glass, soda-lime glass, and low thermal expansion glass (SiO₂—TiO₂ glass, etc.). Among these materials, synthetic quartz glass is particularly preferable as a material for making a transparent substrate of a mask blank for having high transmittance to an ArF exposure light.

### [[Light Shielding Film]]

The light shielding film 2 is a single layer film made of a silicon nitride-based material. The silicon nitride-based material of this disclosure is a material consisting of silicon and nitrogen, or a material consisting of silicon, nitrogen, and one or more elements selected from a metalloid element and a non-metallic element. Further, a single layer film can reduce manufacturing steps and enhances manufacturing efficiency, and can facilitate quality control upon manufacture including defects. Furthermore, the light shielding film 2 has a high Arf light fastness for being made of a silicon nitride-based material.

In addition to silicon, the light shielding film 2 can contain any metalloid elements. Among these metalloid elements, it is preferable to include one or more elements selected from boron, germanium, antimony, and tellurium, since enhancement in conductivity of silicon to be used as a sputtering target can be expected.

In addition to nitrogen, the light shielding film 2 can contain any non-metallic elements. The non-metallic elements in this disclosure indicate those including non-metallic elements in a narrow sense (nitrogen, carbon, oxygen, phosphate, sulfur, selenium, hydrogen), halogen (fluorine, chlorine, bromine, iodine, etc.), and noble gas. Among these non-metallic elements, it is preferable to include one or more elements selected from carbon, fluorine, and hydrogen. In the light shielding film 2, excluding a surface layer region 23 to be mentioned below, it is preferable that oxygen content is reduced to 10 atom % or less, more preferably 5 atom % or less, and further preferable not to positively include oxygen (lower detection limit or less when composition analysis was conducted by X-ray photoelectron spectroscopy, etc.). When the light shielding film 2 contains a large amount of oxygen, a repair rate becomes significantly low upon an EB defect repair.

Noble gas is an element that can increase deposition rate and enhance productivity when present in a film forming chamber upon forming the light shielding film 2 through reactive sputtering. The noble gas is plasmarized and collided on a target so that target-forming elements eject out from the target, and while incorporating reactive gas on the way, the light shielding film 2 is formed on the transparent substrate 1. While the target-forming elements eject out from the target until adhered on the transparent substrate 1, a small amount of noble gas in the film forming chamber is incorporated. Preferable noble gas required for the reactive sputtering includes argon, krypton, and xenon. Further, to mitigate stress of the light shielding film 2, neon and helium having small atomic weight can be positively incorporated into the light shielding film 2.

The light shielding film 2 is preferably made of a material consisting of silicon and nitrogen. As mentioned above, a small amount of noble gas is incorporated when the light shielding film 2 is formed through reactive sputtering. However, noble gas is an element that is difficult to detect even if the light shielding film 2 is subjected to a composition analysis such as RBS (Rutherford Back-Scattering Spectrometry) and XPS (X-ray Photoelectron Spectroscopy). Therefore, the material consisting of silicon and nitrogen can be regarded as including materials containing noble gas.

The interior of the light shielding film 2 can be divided into three regions, namely, a substrate vicinity region (vicinity region) 21, an inner region 22, and a surface layer region 23, in the order from the transparent substrate 1 side. The substrate vicinity region 21 is a region ranging from an interface of the light shielding film 2 and the transparent substrate 1 toward a surface side opposite the transparent substrate 1 (i.e., surface layer region 23 side) up a depth of 5 nm (more preferably, a depth of 4 nm, further preferably, a depth of 3 nm). When the substrate vicinity region 21 is subjected to an X-ray photoelectron spectroscopy, it is likely to be affected by the transparent substrate 1 positioned below. Further, a maximum peak of a photoelectron intensity of Si₂p narrow spectrum of the substrate vicinity region 21 that is acquired has low precision.

The surface layer region 23 is a region ranging from a surface opposite the transparent substrate 1 toward the transparent substrate 1 side up a depth of 5 nm (more preferably, a depth of 4 nm, further preferably, a depth of 3 nm). Since the surface layer region 23 is a region containing oxygen incorporated from a surface of the light shielding film 2, the surface layer region 23 has a structure with a composition gradient in the amount of oxygen content in the film thickness direction (a structure with composition gradient where the amount of oxygen content in the film increases with increasing distance from the transparent substrate 1). Namely, the surface layer region 23 has more oxygen content than the inner region 22. Therefore, unevenness in removal amount in planar view upon an EB defect repair of the oxidized surface layer region 23 is unlikely to occur.

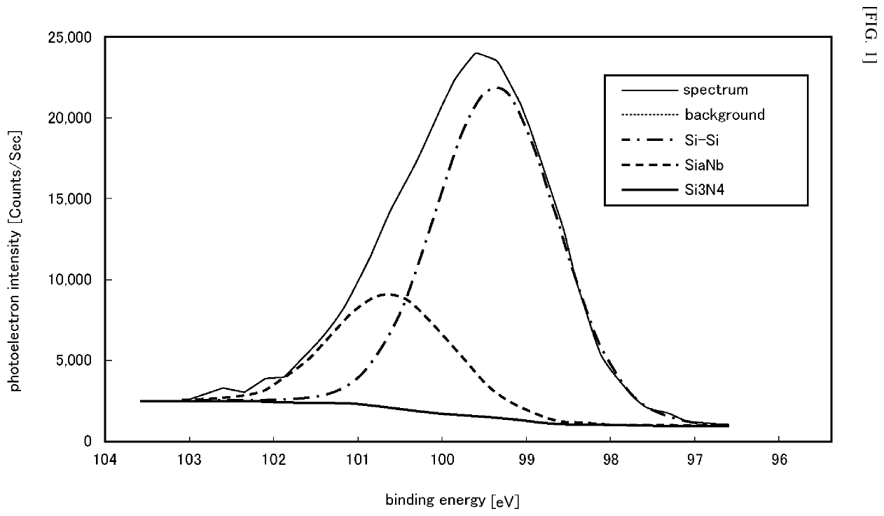

The inner region 22 is a region of the light shielding film 2 excluding the substrate vicinity region 21 and the surface layer region 23. In the inner region 22, a ratio calculated by dividing the number of Si₃N₄ bonds being present in the inner region by a total number of Si₃N₄ bonds, SiₐN_{b} bonds (where a relationship b/[a+b]<4/7 is satisfied), and Si—Si bonds being present in the inner region is 0.04 or less; and a ratio calculated by dividing the number of SiₐN_{b} bonds being present in the inner region by a total number of Si₃N₄ bonds, SiₐN_{b} bonds, and Si—Si bonds being present in the inner region is 0.1 or more. These points are described below along with FIGS. 1 to 3. The inner region 22 has a total content of silicon and nitrogen of preferably 97 atom %, and more preferably, is made from a material having 98 atom % or more. On the other hand, the inner region 22 has a difference of content amount of each element constructing the inner region 22 in film thickness direction of preferably less than 10 atom %. This is for reducing variation in repair rate in removing the inner region 22 by an EB defect repair.

In the substrate vicinity region 21 of an interface with the transparent substrate, since an influence of the composition of the transparent substrate is inevitable when composition analysis such as RBS (Rutherford Back-Scattering Spectrometry) and XPS (X-ray Photoelectron Spectroscopy) is performed, it is difficult to specify the composition and the number of bonds being present. However, the substrate vicinity region 21 is assumed as configured similarly as the inner region 22 described above.

It is most preferable for the light shielding film 2 to have an amorphous structure. This is due to good pattern edge roughness to be achieved when a pattern is formed by etching. In the case of a composition involving difficulty in forming the light shielding film 2 into an amorphous structure, a mixed condition of an amorphous structure and a microcrystalline structure is preferable.

The thickness of the light shielding film 2 is 80 nm or less, more preferably 70 nm or less, and further preferably 60 nm or less. The thickness of 80 nm or less facilitates formation of fine light shielding film pattern, and reduces load in manufacturing a transfer mask from a mask blank having the light shielding film. Further, the thickness of the light shielding film 2 is preferably 40 nm or more, and more preferably 45 nm or more. It will be difficult to obtain a sufficient light shielding performance to an ArF exposure light with the thickness of less than 40 nm. On the other hand, the ratio of the thickness of the inner region 22 to the entire thickness of the light shielding film 2 is preferably 0.7 or more, and more preferably 0.75 or more.

The optical density of the light shielding film 2 to an Arf exposure light is preferably 2.5 or more, and more preferably 3.0 or more. A sufficient light shielding performance can be obtained with an optical density of 2.5 or more. Therefore, when an exposure was carried out using a transfer mask manufactured using this mask blank, it will be easy to obtain a sufficient contrast of the projection optical image (transfer image). Further, the optical density of the light shielding film 2 to an Arf exposure light is preferably 4.0 or less, and more preferably 3.5 or less. The optical density exceeding 4.0 causes the film thickness of the light shielding film 2 to increase, rendering it difficult to form a fine light shielding film pattern.

Incidentally, oxidization is advanced in the light shielding film 2 of a surface layer that is opposite the transparent substrate 1. Therefore, the surface layer of the light shielding film 2 and other regions of the light shielding film 2 have different compositions and different optical characteristics.

Further, the upper portion of the light shielding film 2 can have an anti-reflectance film stacked thereon. Since the anti-reflectance film contains oxygen incorporated from the surface and contains more oxygen than the light shielding film 2, unevenness of removal amount in planar view upon an EB defect repair is unlikely to occur.

In the X-ray photoelectron spectroscopy described above, while any of AlKα ray and MgKα ray is applicable as the X-ray to be irradiated on the light shielding film 2, AlKα ray is preferably used. Incidentally, described herein is the case of conducting an X-ray photoelectron spectroscopy using an X-ray of AlKα ray.

Method of obtaining Si₂p narrow spectrum through X-ray photoelectron spectroscopy on the light shielding film 2 is generally carried out by the following procedures. Namely, initially, wide-scanning is carried out to acquire photoelectron intensity (number of discharge of photoelectrons per unit time from X ray-irradiated measurement object) at a bandwidth of a wide range of binding energy to acquire wide spectrum, and the peak derived from the constituent elements of the light shielding film 2 is specified. Subsequently, narrow spectrum is acquired by performing narrow scanning, which has higher resolution than wide scan but bandwidth of binding energy that can be obtained is narrow, with bandwidth around the peak of interest (in this case, Si₂p). On the other hand, the constituent elements of the light shielding film 2 which is an object to be measured using X-ray photoelectron spectroscopy were known previously. Further, the narrow spectrums that are necessary in this disclosure are limited to Si₂p narrow spectrum and Nls narrow spectrum. Therefore, in this disclosure, the step of obtaining the wide spectrum can be omitted and Si₂p narrow spectrum can be obtained.

The maximum peak of photoelectron intensity of Si₂p narrow spectrum acquired by performing an X-ray photoelectron spectroscopy is preferably a maximum peak within a range of 97 [eV] or more and 103 [eV] or less binding energy. This is because the peak out of the range of the binding energy may not be photoelectrons that are discharged from Si—N bond.

While the light shielding film 2 is made by sputtering, any sputtering method is applicable such as DC sputtering, RF sputtering, and ion beam sputtering. In the case of using a target with low conductivity (silicon target, silicon compound target free of or including a small amount of metalloid element, etc.), application of RF sputtering and ion beam sputtering is preferable. However, application of RF sputtering is more preferable, considering the deposition rate. A method for manufacturing the mask blank 100 preferably includes at least the step of forming the light shielding film 2 on the transparent substrate 1 by reactive sputtering using a silicon target or a target made of a material containing silicon and one or more elements selected from a metalloid element and a non-metallic element in sputtering gas containing nitrogen-based gas and noble gas.

The optical density of the light shielding film 2 is determined not only by the composition of the light shielding film 2. Film density and crystal condition of the light shielding film 2 are also the factors that affect optical density. Therefore, various conditions in making the light shielding film 2 by reactive sputtering are adjusted so that the optical density to an ArF exposure light falls within the predefined value. For allowing the optical density of the light shielding film 2 to fall within the range of the predefined value, not only the ratio of mixed gas of noble gas and reactive gas is adjusted in making a film by reactive sputtering, but various other adjustments are made upon making a film by reactive sputtering, such as pressure in a film forming chamber, power applied to the target, and positional relationship such as distance between the target and the transparent substrate. Further, these film forming conditions are unique to film forming apparatuses which are adjusted arbitrarily so that the light shielding film 2 to be formed reaches a desired optical density.

Nitrogen-based gas used as sputtering gas in making the light shielding film 2 can be any gas as long as the gas contains nitrogen. As mentioned above, since it is preferable that the light shielding film 2 has less oxygen content excluding the surface layer, it is preferable to apply nitrogen-based gas free of oxygen, and it is more preferable to apply nitrogen gas (N₂ gas). Although there is no limitation to the type of noble gas to be used as sputtering gas in making the light shielding film 2, it is preferable to use argon, krypton, and xenon. Further, to mitigate stress of the light shielding film 2, neon and helium having small atomic weight can be positively incorporated into the light shielding film 2.

### [[Hard Mask Film]]

In the mask blank 100 having the light shielding film 2, a preferable configuration is that a hard mask film 3 made of a material having etching selectivity to etching gas used in etching the light shielding film 2 is further stacked on the light shielding film 2. Since the light shielding film 2 must secure a predetermined optical density, there is a limitation to reduce its thickness. It is sufficient for the hard mask film 3 to have a film thickness that can function as an etching mask until completion of dry etching for forming a pattern in the light shielding film 2 immediately below, and basically is not optically limited. Therefore, the thickness of the hard mask film 3 can be reduced significantly compared to the thickness of the light shielding film 2. It is sufficient for the resist film of an organic-based material to have a film thickness that can function as an etching mask until dry etching for forming a pattern in the hard mask film 3 is completed. Therefore, the thickness of the resist film can be reduced significantly compared to conventional structures. Therefore, problems such as collapse of resist pattern can be inhibited.

The hard mask film 3 is preferably made of a material containing chromium (Cr). Materials containing chromium have particularly high dry etching durability to dry etching using fluorine-based gas such as SF₆. A thin film made of materials containing chromium is generally patterned through dry etching with mixed gas of chlorine-based gas and oxygen gas. However, since anisotropy is not as high in this dry etching, an etching to the side wall direction of a pattern (side etching) is likely to advance upon dry etching in patterning a thin film from materials containing chromium.

In the case where a material containing chromium was used in the light shielding film, due to relatively thick film thickness of the light shielding film 2, a problem of side etching occurs upon dry etching of the light shielding film 2. However, when a material containing chromium was used as the hard mask film 3, the problem caused by side etching is unlikely to occur due to the relatively thin film thickness of the hard mask film 3.

Materials containing chromium can include, in addition to chromium metal, a material containing chromium and one or more elements selected from oxygen, nitrogen, carbon, boron, and fluorine, for example, CrN, CrC, CrON, CrCO, and CrCON. When these elements are added to chromium metal, the film is likely to become an amorphous structure film, and it is preferable since the surface roughness of the film and line edge roughness when the light shielding film 2 is subjected to dry etching can be inhibited.

Further, from the viewpoint of dry etching of the hard mask film 3 as well, it is preferable to use a material containing chromium and one or more elements selected from oxygen, nitrogen, carbon, boron, and fluorine as materials for making the hard mask film 3.

While a chromium-based material is etched by mixed gas of chlorine-based gas and oxygen gas, etching rate of the chromium metal to the etching gas is not as high. By chromium containing one or more elements selected from oxygen, nitrogen, carbon, boron, and fluorine, it is possible to enhance the etching rate of mixed gas of chlorine-based gas and oxygen gas to etching gas.

Incidentally, the hard mask film 3 made of CrCO is particularly preferable for being free of nitrogen that is likely to cause large side etching in dry etching by mixed gas of chlorine-based gas and oxygen gas, contains carbon that inhibits side etching, and further contains oxygen that enhances etching rate. Further, a material containing chromium for forming the hard mask film 3 can contain one or more elements selected from indium, molybdenum, and tin. By containing one or more elements selected from indium, molybdenum, and tin, it is possible to further enhance the etching rate to mixed gas of chlorine-based gas and oxygen gas.

In the mask blank 100, a resist film of an organic material is preferably formed in contact with the surface of the hard mask film 3 at a resist film thickness of 100 nm or less. In the case of a fine pattern applicable to DRAM hp32 nm generation, a SRAF (Sub-Resolution Assist Feature) with 40 nm line width may be provided on a transfer pattern to be formed on the hard mask film 3. However, even in this case, the cross-sectional aspect ratio of the resist pattern can be reduced down to 1:2.5 so that collapse and peeling off of the resist pattern can be prevented in rinsing and developing, etc. of the resist film. Incidentally, the resist film preferably has a film thickness of 80 nm or less.

On the mask blank 100, it is possible to form the resist film directly in contact with the light shielding film 2 without the hard mask film 3. In this case, since the structure is simple and dry etching of the hard mask film 3 will be unnecessary in manufacturing a transfer mask, it will be possible to reduce the number of manufacturing procedures. Incidentally in this case, it is preferable to form a resist film after the light shielding film 2 has been subjected to surface treatment such as HMDS (hexamethyldisilazane).

Further, while the mask blank of this disclosure is suitable for binary mask applications as will be mentioned below, the application is not limited to a binary mask, but can be used for a mask blank for Levenson type phase shift mask, or a mask blank for CPL (Chromeless Phase Lithography) mask.

### [Transfer Mask]

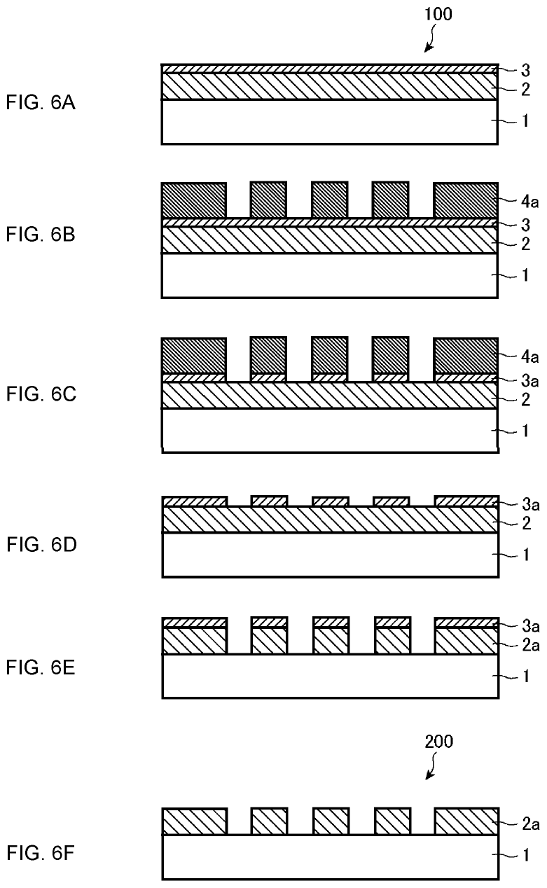

FIGS. 6A-6F are schematic cross-sectional views showing the steps of manufacturing the transfer mask (binary mask) 200 from the mask blank 100 of an embodiment of this disclosure.

The method of manufacturing the transfer mask 200 shown in FIGS. 6A-6F is featured in utilizing the mask blank 100 described above, including the steps of forming a transfer pattern in the hard mask film 3 by dry etching, forming a transfer pattern in the light shielding film 2 by dry etching with the hard mask film 3 (hard mask pattern 3a) having a transfer pattern as a mask, and removing the hard mask pattern 3a.

One example of the method of manufacturing the transfer mask 200 is explained below according to the manufacturing steps shown in FIGS. 6A-6F. In this example, a material containing silicon and nitrogen is used for the light shielding film 2, and a material containing chromium is used for the hard mask film 3.

First, the mask blank 100 (see FIG. 6A) is prepared, and a resist film is formed in contact with the hard mask film 3 by spin coating. Next, a transfer pattern to be formed in the light shielding film 2 is exposed and written on the resist film, and predetermined treatments such as developing are further conducted, to thereby form a resist pattern 4a (see FIG. 6B). At this stage, a program defect was added to the resist pattern 4a that was written by electron beam in addition to the light shielding film pattern that is to be originally formed, so that a black defect is formed on the light shielding film 2.

Next, dry etching is conducted using chlorine-based gas such as mixed gas of chlorine and oxygen with the resist pattern 4a as a mask, and a pattern (hard mask pattern 3a) is formed in the hard mask film 3 (see FIG. 6C). There is no particular limitation to chlorine-based gas as long as Cl is included, for example, Cl₂, SiCl₂, CHCl₃, CH₂Cl₂, and BCl₃. In the case of using mixed gas of chlorine and oxygen, the gas flow ratio is preferably, for example, Cl₂:O₂=4:1.

Next, the resist pattern 4a is removed by ashing or by using resist peeling liquid (see FIG. 6D).

Next, dry etching is conducted using fluorine-based gas with the hard mask pattern 3a as a mask, and a pattern (light shielding film pattern 2a) is formed in the shielding film 2 (see FIG. 6E). Any fluorine-based gas can be used as long as the gas includes F, preferably SF₆. While CHF₃, CF₄, C₂F₆, C₄F₈, etc. can be given as examples other than SF₆, fluorine-based gas containing C has relatively high etching rate to the transparent substrate 1 of a glass material. SF₆ is preferable for causing less damage on the transparent substrate 1. It is further preferable to add He, etc. to SF₆.

Thereafter, the hard mask pattern 3a is removed using a chromium etching liquid, predetermined treatments such as cleaning are conducted, and the transfer mask 200 is obtained (see FIG. 6F). Incidentally, this step of removing the hard mask pattern 3a can be carried out by dry etching using mixed gas of chlorine and oxygen. A mixture containing cerium diammonium nitrate and perchloric acid can be given as the chromium etching liquid.

The transfer mask 200 manufactured by the manufacturing method shown in FIGS. 6A-6F is a binary mask having a light shielding film 2 (light shielding film pattern 2a) having a transfer pattern on the transparent substrate 1. The manufactured transfer mask 200 of Example 1 was subjected to mask pattern inspection by a mask inspection apparatus, and the presence of a black defect was confirmed on the light shielding film pattern 2a of a location where a program defect was arranged. Therefore, the black defect portion was removed by an EB defect repair.

Manufacturing the transfer mask 200 as described above can suppress generation of surface roughness of the transparent substrate 1 near the black defect portion and can also suppress generation of a spontaneous etching in the light shielding film pattern 2a when an EB defect repair was performed on a black defect portion of the light shielding film pattern 2a during manufacture of the transfer mask 200.

While an explanation was made herein on the case where the transfer mask 200 is a binary mask, the transfer mask of this disclosure is not limited to application to a binary mask, but can be used for a Levenson type phase shift mask and a CPL mask. Namely, in the case of a Levenson type phase shift mask, the light shielding film of this disclosure can be used as its light shielding film. Further, in the case of a CPL mask, the light shielding film of this disclosure can be used mainly in a region including a light shielding band on the outer periphery.

Further, the method of manufacturing a semiconductor device of this disclosure is featured in including the step of exposure-transferring a transfer pattern in a resist film on a semiconductor substrate using the transfer mask 200 manufactured by using the transfer mask 200 or the mask blank 100.

Since the transfer mask 200 and the mask blank 100 of this disclosure have the effects as described above, when the transfer mask 200 is set on a mask stage of an exposure apparatus using ArF excimer laser as an exposure light and a transfer pattern is exposure-transferred in a resist film on a semiconductor device, a transfer pattern can be transferred in the resist film on the semiconductor device at a high CD precision. Therefore, in the case where a lower layer film below the resist film was dry etched to form a circuit pattern using the pattern of the resist film as a mask, a highly precise circuit pattern without short-circuit of wiring and disconnection caused by insufficient precision can be formed.

### EXAMPLES

The embodiments of this disclosure are described in greater detail below together with examples.

### Example 1

### [Manufacture of Mask Blank]

A transparent substrate 1 made of a synthetic quartz glass with a size of a main surface of about 152 mm×about 152 mm and a thickness of about 6.25 mm was prepared. An end surface and the main surface of the transparent substrate 1 were polished to a predetermined surface roughness, and thereafter subjected to predetermined cleaning treatment and drying treatment.

Next, the transparent substrate 1 was placed in a single-wafer RF sputtering apparatus, and by reactive sputtering (RF sputtering) using a silicon (Si) target, with mixed gas of argon (Ar), nitrogen (N₂), and helium (He) (flow ratio Ar:N₂:He=30:3:100) as sputtering gas, a light shielding film 2 made of silicon and nitrogen was formed on the transparent substrate 1 with a thickness of 50.0 nm. Electric power of RF power source during sputtering was 1500 W.

Next, for the purpose of adjusting stress of the film, the transparent substrate 1 having the light shielding film 2 formed thereon was subjected to heat treatment under the condition of 500° C. heating temperature in the atmosphere for the processing time of one hour.

A spectrophotometer (Cary4000 manufactured by Agilent Technologies) was used to measure an optical density (OD) of the light shielding film 2 after the heat treatment under 193 nm wavelength, and the value was 3.02. In view of this result, the mask blank of Example 1 has high light shielding performance that is necessary.

Another light shielding film was formed on a main surface of another transparent substrate under the same film forming condition as the light shielding film 2 of Example 1, and further subjected to heat treatment under the same condition. Next, the light shielding film of the other transparent substrate after the heat treatment was subjected to X-ray photoelectron spectroscopy. In the X-ray photoelectron spectroscopy, the steps of irradiating an X-ray (AlKα ray: 1486 eV) on the surface of the light shielding film to measure the intensity of photoelectrons emitted from the light shielding film, digging the surface of the light shielding film by Ar gas sputtering for a depth up to 0.65 nm, and irradiating an X-ray on the light shielding film of the dug region to measure the intensity of photoelectrons emitted from that region were repeated, and Si₂p narrow spectrum of each depth of the light shielding film was obtained, respectively. Since the transparent substrate 1 is an insulating body, energy of the obtained Si₂p narrow spectrum deviates at a rather low level compared to the spectrum when analyzed on a conductive body. To correct this deviation, correction is made to correspond to the peak of a carbon which is a conductive body (the same for Examples 2 to 5 and Comparative Examples 1 and 2 below).

The obtained Si₂p narrow spectrum includes a peak for each of Si—Si bond, SiₐN_{b} bond, and Si₃N₄ bond. Each peak position of Si—Si bond, SiₐN_{b} bond, and Si₃N₄ bond, and full width at half maximum FWHM were fixed and a peak resolution was made. Concretely, a peak resolution was made with the peak position of Si—Si bond at 99.35 eV, the peak position of SiₐN_{b} bond at 100.6 eV, the peak position of Si₃N₄ bond at 101.81 eV, and each full width at half maximum FWHM at 1.71 (the same for Examples 2 to 5 and Comparative Examples 1 and 2 below). For each spectrum of the peak resolved Si—Si bond, SiₐN_{b} bond, and Si₃N₄ bond, an area was calculated respectively by subtracting a background calculated by an algorithm of publicly known methods of the analysis instrument, and based on each area calculated, the ratios of the number of Si—Si bonds, SiₐN_{b} bonds, and Si₃N₄ bonds being present were calculated.

FIG. 1 is a result of an X-ray photoelectron spectroscopy on the light shielding film of the mask blank according to Example 1, among of which Si₂p narrow spectrum at a predetermined depth within a range of the inner region is shown. As shown in the drawing, on the Si₂p narrow spectrum, a peak resolution was made on each of the Si—Si bond, SiₐN_{b} bond, and Si₃N₄ bond, an area was calculated by subtracting the background, and the ratios of the number of Si—Si bonds, SiₐN_{b} bonds, and Si₃N₄ bonds being present were calculated. As a result, the ratio of the number of Si—Si bonds being present was 0.746, the ratio of the number of SiₐN_{b} bonds being present was 0.254, and the ratio of the number of Si₃N₄ bonds being present was 0.000. Namely, the condition of which the ratio calculated by dividing the number of Si₃N₄ bonds being present in the inner region by a total number of Si₃N₄ bonds, SiₐN_{b} bonds, and Si—Si bonds being present in the inner region is 0.04 or less, and the condition of which the ratio calculated by dividing the number of SiₐN_{b} bonds being present in the inner region by the total number of Si₃N₄ bonds, SiₐN_{b} bonds, and Si—Si bonds being present in the inner region is 0.1 or more were both satisfied (the former condition is satisfied by 0.000, and the latter condition is satisfied by 0.254).

Further, among the Si₂p narrow spectrum of each depth of the obtained light shielding film, the ratios of the number of Si—Si bonds, SiₐN_{b} bonds, and Si₃N₄ bonds being present were calculated under the same procedure for each Si₂p narrow spectrum of the depth other than those shown in FIG. 1 corresponding to the inner region of the light shielding film. As a result, the ratios of the number of Si—Si bonds, SiₐN_{b} bonds, and Si₃N₄ bonds being present of all depths of the inner region showed similar tendency as the ratios of the number of Si—Si bonds, SiₐN_{b} bonds, and Si₃N₄ bonds being present of the depth shown in FIG. 1. Further, all satisfied the two conditions regarding the ratio of the number present described above.

Moreover, in view of these results of the X-ray photoelectron spectroscopy, the average composition of the inner region of the light shielding film was found out to be Si:N:O=75.5:23.2:1.3 (atomic % ratio). Incidentally, this X-ray photoelectron spectroscopy was carried out using AlKα ray (1486.6 eV) as an X ray, under the conditions of 200 μmφ photoelectron detection area and 45 deg take-off angle (the same for to Examples 2 to 5 and Comparative Examples 1 and 2 below).

Next, the transparent substrate 1 having the light shielding film 2 formed after heat treatment was placed in a single-wafer DC sputtering apparatus, and by reactive sputtering (DC sputtering) using a chromium (Cr) target, with mixed gas atmosphere of argon (Ar) and nitrogen (N₂), a hard mask film 3 made of a CrN film was formed having a film thickness of 5 nm. This film measured with XPS had film composition ratio of 75 atom % Cr and 25 atom % N. Thereafter, a heat treatment was performed under a temperature that is lower (280° C.) than the heat treatment performed on the light shielding film 2, and stress of the hard mask film 3 was adjusted.

Through the above procedures, the mask blank 100 having a structure where the light shielding film 2 and the hard mask film 3 are stacked on the transparent substrate 1 was manufactured.

### [Manufacture of Transfer Mask]

Next, using the mask blank 100 of Example 1, a transfer mask (binary mask) 200 of Example 1 was manufactured through the following procedure.

First, the mask blank 100 of Example 1 (see FIG. 6A) was prepared, and a resist film of a chemically amplified resist for electron beam writing was formed in contact with the surface of the hard mask film 3 at a film thickness of 80 nm. Next, a transfer pattern to be formed in the light shielding film 2 was written on the resist film by an electron beam, and predetermined treatments such as developing and cleaning were conducted, to thereby form a resist pattern 4a (see FIG. 6B). At this stage, a program defect was added to the resist pattern 4a that was written by electron beam in addition to the light shielding film pattern that is to be originally formed, so that a black defect is formed on the light shielding film 2.

Next, dry etching was conducted using mixed gas of chlorine and oxygen (gas flow ratio Cl₂:O₂=4:1) with the resist pattern 4a as a mask, and a pattern (hard mask pattern 3a) was formed in the hard mask film 3 (see FIG. 6C).

Next, the resist pattern 4a was removed (see FIG. 6D). Next, dry etching was conducted using fluorine-based gas (mixed gas of SF₆ and He) with the hard mask pattern 3a as a mask, and a pattern (light shielding film pattern 2a) was formed in the light shielding film 2 (see FIG. 6E).

Thereafter, the hard mask pattern 3a was removed using a chromium etching liquid including cerium diammonium nitrate and perchloric acid, predetermined treatments such as cleaning were conducted, and the transfer mask 200 was obtained (see FIG. 6F).

The manufactured transfer mask 200 of Example 1 was subjected to mask pattern inspection by a mask inspection apparatus, and the presence of a black defect was confirmed on the light shielding film pattern 2a of a location where a program defect was arranged. The black defect portion was subjected to an EB defect repair. The repair rate ratio of the light shielding film pattern 2a relative to the transparent substrate 1 (repair rate of the light shielding film pattern 2a to repair rate of the transparent substrate 1) was sufficiently high, and etching on the surface of the transparent substrate 1 could be minimized.

A simulation of a transfer image was made when an exposure transfer was made on a resist film on a semiconductor device using AIMS193 (manufactured by Carl Zeiss) at an exposure light of wavelength 193 nm on the transfer mask 200 of Example 1 after the EB defect repair. The simulated exposure transfer image was inspected, and the design specification was fully satisfied. Further, the transfer image of the portion subjected to the EB defect repair was at a comparable level to the transfer images of other regions. In view of the above result, it can be considered that when an EB defect repair was performed on a black defect portion of the light shielding film pattern 2a of the transfer mask 200 of Example 1, generation of surface roughness of the transparent substrate 1 can be suppressed and generation of a spontaneous etching in the light shielding film pattern 2a can also be suppressed. Further, it can be considered that when the transfer mask 200 of Example 1 after an EB defect repair was set on a mask stage of an exposure apparatus and exposure-transferred on a resist film on a semiconductor device, a circuit pattern to be finally formed on the semiconductor device is formed at a high precision. Therefore, the transfer mask 200 manufactured by the method of manufacturing the transfer mask of Example 1 is considered as resulting in a transfer mask having high transfer precision.

### Example 2

### [Manufacture of Mask Blank]

The mask blank of Example 2 was manufactured by the same procedure as the mask blank 100 of Example 1, except for the light shielding film which was made as below.

The method of making the light shielding film of Example 2 is as described below.

The transparent substrate 1 was placed in a single-wafer RF sputtering apparatus, and by reactive sputtering by RF power source (RF sputtering) using a silicon (Si) target, with mixed gas of argon (Ar), nitrogen (N₂), and helium (He) (flow ratio Ar:N₂:He=30:2.3:100) as sputtering gas, a light shielding film 2 made of silicon and nitrogen was formed on the transparent substrate 1 with a thickness of 41.5 nm. Electric power of RF power source during sputtering was 1500 W.

Similar to Example 1, the transparent substrate 1 on which the light shielding film 2 was formed was subjected to heat treatment, and the optical density (OD) of the light shielding film 2 after the heat treatment was measured as 2.58. In view of this result, the mask blank of Example 2 has light shielding performance that is necessary.

Similar to Example 1, another light shielding film was formed on a main surface of another transparent substrate under the same film forming condition as the light shielding film 2 of Example 2, and further subjected to heat treatment under the same condition. Next, through the same procedure as Example 1, the light shielding film of the other transparent substrate after the heat treatment of Example 2 was subjected to X-ray photoelectron spectroscopy. Further, among the Si₂p narrow spectrum of each depth of the obtained light shielding film, the ratios of the number of Si—Si bonds, SiₐN_{b} bonds, and Si₃N₄ bonds being present were calculated under the same procedure as Example 1 based on Si₂p narrow spectrum of the predetermined depth corresponding to the inner region of the light shielding film. As a result, the ratio of the number of Si—Si bonds being present was 0.898, the ratio of the number of SiₐN_{b} bonds being present was 0.102, and the ratio of the number of Si₃N₄ bonds being present was 0.000. Namely, the condition of which the ratio calculated by dividing the number of Si₃N₄ bonds being present in the inner region by the total number of Si₃N₄ bonds, SiₐN_{b} bonds, and Si—Si bonds being present in the inner region is 0.04 or less, and the condition of which the ratio calculated by dividing the number of SiₐN_{b} bonds being present by the total number of Si₃N₄ bonds, SiₐN_{b} bonds, and Si—Si bonds being present in the inner region is 0.1 or more were both satisfied (the former condition is satisfied by 0.000, and the latter condition is satisfied by 0.102).

Further, similar to Example 1, among the Si₂p narrow spectrum of each depth of the light shielding film obtained in Example 2, the ratios of the number of Si—Si bonds, SiₐN_{b} bonds, and Si₃N₄ bonds being present were calculated under the same procedure for each Si₂p narrow spectrum of the depth other than the predetermined depth corresponding to the inner region of the light shielding film. The ratios of the number of Si—Si bonds, SiₐN_{b} bonds, and Si₃N₄ bonds being present of any depth of the inner region showed similar tendency as the ratios of the number of Si—Si bonds, SiₐN_{b} bonds, and Si₃N₄ bonds being present of the predetermined depth. Further, all satisfied the two conditions regarding the ratio of the number present described above.

Thereafter, through the same procedure as Example 1, the mask blank 100 having a structure where the light shielding film 2 and the hard mask film 3 are stacked on the transparent substrate 1 was manufactured.

### [Manufacture of Transfer Mask]

Next, using the mask blank of Example 2, a transfer mask (binary mask) of Example 2 was manufactured through the same procedure as Example 1.

The manufactured transfer mask 200 of Example 1 was subjected to mask pattern inspection by a mask inspection apparatus, and the presence of a black defect was confirmed on the light shielding film pattern 2a of a location where a program defect was arranged. The black defect portion was subjected to an EB defect repair. The repair rate ratio of the light shielding film pattern 2a relative to the transparent substrate 1 was sufficiently high, and etching on the surface of the transparent substrate 1 could be minimized.

A simulation of a transfer image was made when an exposure transfer was made on a resist film on a semiconductor device using AIMS193 (manufactured by Carl Zeiss) at an exposure light of wavelength 193 nm on the transfer mask 200 of Example 2 after the EB defect repair. The simulated exposure transfer image was inspected, and the design specification was fully satisfied. Further, the transfer image of the portion subjected to the EB defect repair was at a comparable level to the transfer images of other regions. In view of the above result, it can be considered that when an EB defect repair was performed on a black defect portion of the light shielding film pattern 2a of the transfer mask 200 of Example 2, generation of surface roughness of the transparent substrate 1 can be suppressed and generation of a spontaneous etching in the light shielding film pattern 2a can also be suppressed. Further, it can be considered that when the transfer mask 200 of Example 2 after the EB defect repair was set on a mask stage of an exposure apparatus and exposure-transferred on a resist film on a semiconductor device, a circuit pattern to be finally formed on the semiconductor device is formed at a high precision. Therefore, the transfer mask 200 manufactured by the method of manufacturing the transfer mask of Example 2 is considered as resulting in a transfer mask having high transfer precision.

### Example 3

### [Manufacture of Mask Blank]

The mask blank of Example 3 was manufactured by the same procedure as the mask blank 100 of Example 1, except for the light shielding film which was made as below.

The method of forming the light shielding film of Example 3 is as described below.

The transparent substrate 1 was placed in a single-wafer RF sputtering apparatus, and by reactive sputtering by RF power source (RF sputtering) using a silicon (Si) target, with mixed gas of argon (Ar), nitrogen (N₂), and helium (He) (flow ratio Ar:N₂:He=30:5.8:100) as sputtering gas, a light shielding film 2 made of silicon and nitrogen was formed on the transparent substrate 1 with a thickness of 52.4 nm. Electric power of RF power source during sputtering was 1500 W.

Similar to Example 1, the transparent substrate 1 on which the light shielding film 2 was formed was subjected to heat treatment, and the optical density (OD) of the light shielding film 2 after the heat treatment was measured as 3.05. In view of this result, the mask blank of Example 3 has high light shielding performance that is necessary.

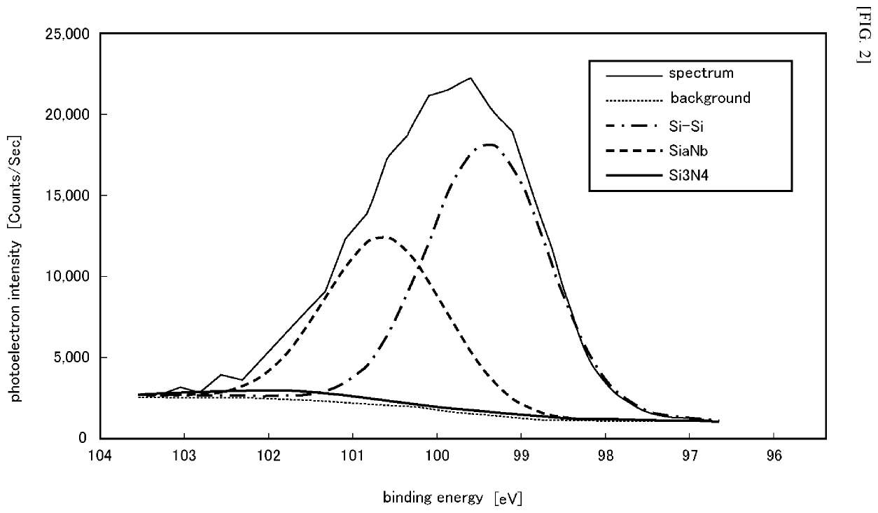

Similar to Example 1, another light shielding film was formed on a main surface of another transparent substrate under the same film forming condition as the light shielding film 2 of Example 3, and further subjected to heat treatment under the same condition. Next, through the same procedure as Example 1, the light shielding film of the other transparent substrate after the heat treatment of Example 3 was subjected to X-ray photoelectron spectroscopy. Further, among the Si₂p narrow spectrum of each depth of the obtained light shielding film, the ratios of the number of Si—Si bonds, SiₐN_{b} bonds, and Si₃N₄ bonds being present were calculated under the same procedure as Example 1 based on Si₂p narrow spectrum (see FIG. 2) of the predetermined corresponding to the inner region of the light shielding film. As a result, the ratio of the number of Si—Si bonds being present was 0.605, the ratio of the number of SiₐN_{b} bonds being present was 0.373, and the ratio of the number of Si₃N₄ bonds being present was 0.022. Namely, the condition of which the ratio calculated by dividing the number of Si₃N₄ bonds being present in the inner region by the total number of Si₃N₄ bonds, SiₐN_{b} bonds, and Si—Si bonds being present in the inner region is 0.04 or less, and the condition of which the ratio calculated by dividing the number of SiₐN_{b} bonds being present in the inner region by the total number of Si₃N₄ bonds, SiₐN_{b} bonds, and Si—Si bonds being present in the inner region is 0.1 or more were both satisfied (the former condition is satisfied by 0.022, and the latter condition is satisfied by 0.373).

Further, similar to Example 1, among the Si₂p narrow spectrum of each depth of the light shielding film obtained in Example 3, the ratios of the number of Si—Si bonds, SiₐN_{b} bonds, and Si₃N₄ bonds being present were calculated under the same procedure for each Si₂p narrow spectrum of the depth other than the predetermined depth corresponding to the inner region of the light shielding film. The ratios of the number of Si—Si bonds, SiₐN_{b} bonds, and Si₃N₄ bonds being present of any depth of the inner region showed similar tendency as the ratio of the number of Si—Si bonds, SiₐN_{b} bonds, and Si₃N₄ bonds being present of the predetermined depth. Further, all satisfied the two conditions regarding the ratio of the number present described above.

Thereafter, through the same procedure as Example 1, the mask blank 100 having a structure where the light shielding film 2 and the hard mask film 3 are stacked on the transparent substrate 1 was manufactured.

### [Manufacture of Transfer Mask]

Next, using the mask blank of Example 3, a transfer mask (binary mask) of Example 3 was manufactured through the same procedure as Example 1.

The manufactured transfer mask 200 of Example 3 was subjected to mask pattern inspection by a mask inspection apparatus, and the presence of a black defect was confirmed on the light shielding film pattern 2a of a location where a program defect was arranged. The black defect portion was subjected to an EB defect repair. The repair rate ratio of the light shielding film pattern 2a relative to the transparent substrate 1 was sufficiently high, and etching on the surface of the transparent substrate 1 could be minimized.

A simulation of a transfer image was made when an exposure transfer was made on a resist film on a semiconductor device using AIMS193 (manufactured by Carl Zeiss) at an exposure light of wavelength 193 nm on the transfer mask 200 of Example 3 after the EB defect repair. The simulated exposure transfer image was inspected, and the design specification was fully satisfied. Further, the transfer image of the portion subjected to the EB defect repair was at a comparable level to the transfer images of other regions. In view of the above result, it can be considered that when an EB defect repair was performed on a black defect portion of the light shielding film pattern 2a of the transfer mask 200 of Example 3, generation of surface roughness of the transparent substrate 1 can be suppressed and generation of a spontaneous etching in the light shielding film pattern 2a can also be suppressed. Further, it can be considered that when the transfer mask 200 of Example 3 after the EB defect repair was set on a mask stage of an exposure apparatus and exposure-transferred on a resist film on a semiconductor device, a circuit pattern to be finally formed on the semiconductor device is formed at a high precision. Therefore, the transfer mask 200 manufactured by the method of manufacturing the transfer mask of Example 3 is considered as resulting in a transfer mask having high transfer precision.

### Example 4

### [Manufacture of Mask Blank]

The mask blank of Example 4 was manufactured by the same procedure as the mask blank 100 of Example 1, except for the light shielding film which was made as below.

The method of forming the light shielding film of Example 4 is as described below.

The transparent substrate 1 was placed in a single-wafer RF sputtering apparatus, and by reactive sputtering by RF power source (RF sputtering) using a silicon (Si) target, with mixed gas of argon (Ar), nitrogen (N₂), and helium (He) (flow ratio Ar:N₂:He=30:6.6:100) as sputtering gas, a light shielding film 2 made of silicon and nitrogen was formed on the transparent substrate 1 with a thickness of 45.1 nm. Electric power of RF power source during sputtering was 1500 W.

Similar to Example 1, the transparent substrate 1 on which the light shielding film 2 was formed was subjected to heat treatment, and the optical density (OD) of the light shielding film 2 after the heat treatment was measured as 2.54. In view of this result, the mask blank of Example 4 has light shielding performance that is necessary.

Similar to Example 1, another light shielding film was formed on a main surface of another transparent substrate under the same film forming condition as the light shielding film 2 of Example 4, and further subjected to heat treatment under the same condition. Next, through the same procedure as Example 1, the light shielding film of the other transparent substrate after the heat treatment of Example 4 was subjected to X-ray photoelectron spectroscopy. Further, among the Si₂p narrow spectrum of each depth of the obtained light shielding film, the ratios of the number of Si—Si bonds, SiₐN_{b} bonds, and Si₃N₄ bonds being present were calculated under the same procedure as Example 1 for each Si₂p narrow spectrum of the predetermined depth corresponding to the inner region of the light shielding film. As a result, the ratio of the number of Si—Si bonds being present was 0.584, the ratio of the number of SiₐN_{b} bonds being present was 0.376, and the ratio of the number of Si₃N₄ bonds being present was 0.040. Namely, the condition of which the ratio calculated by dividing the number of Si₃N₄ bonds being present in the inner region by the total number of Si₃N₄ bonds, SiₐN_{b} bonds, and Si—Si bonds being present in the inner region is 0.04 or less, and the condition of which the ratio calculated by dividing the number of SiₐN_{b} bonds being present in the inner region by the total number of Si₃N₄ bonds, SiₐN_{b} bonds, and Si—Si bonds being present in the inner region is 0.1 or more were both satisfied (the former condition is satisfied by 0.040, and the latter condition is satisfied by 0.376).

Further, similar to Example 1, among the Si₂p narrow spectrum of each depth of the light shielding film obtained in Example 4, the ratios of the number of Si—Si bonds, SiₐN_{b} bonds, and Si₃N₄ bonds being present were calculated under the same procedure for each Si₂p narrow spectrum of the depth other than the predetermined depth corresponding to the inner region of the light shielding film. The ratios of the number of Si—Si bonds, SiₐN_{b} bonds, and Si₃N₄ bonds being present of any depth of the inner region showed similar tendency as the ratios of the number of Si—Si bonds, SiₐN_{b} bonds, and Si₃N₄ bonds being present of the predetermined depth. Further, all satisfied the two conditions regarding the ratio of the number present described above.

Thereafter, through the same procedure as Example 1, the mask blank 100 having a structure where the light shielding film 2 and the hard mask film 3 are stacked on the transparent substrate 1 was manufactured.

### [Manufacture of Transfer Mask]

Next, using the mask blank of Example 4, a transfer mask (binary mask) of Example 4 was manufactured through the same procedure as Example 1.

The manufactured transfer mask 200 of Example 1 was subjected to mask pattern inspection by a mask inspection apparatus, and the presence of a black defect was confirmed on the light shielding film pattern 2a of a location where a program defect was arranged. The black defect portion was subjected to an EB defect repair. The repair rate ratio of the light shielding film pattern 2a relative to the transparent substrate 1 was sufficiently high, and etching on the surface of the transparent substrate 1 could be minimized.

A simulation of a transfer image was made when an exposure transfer was made on a resist film on a semiconductor device using AIMS193 (manufactured by Carl Zeiss) at an exposure light of wavelength 193 nm on the transfer mask 200 of Example 4 after the EB defect repair. The simulated exposure transfer image was inspected, and the design specification was fully satisfied. Further, the transfer image of the portion subjected to the EB defect repair was at a comparable level to the transfer images of other regions. In view of the above result, it can be considered that when an EB defect repair was performed on a black defect portion of the light shielding film pattern 2a of the transfer mask 200 of Example 4, generation of surface roughness of the transparent substrate 1 can be suppressed and generation of a spontaneous etching in the light shielding film pattern 2a can also be suppressed. Further, it can be considered that when the transfer mask 200 of Example 4 after the EB defect repair was set on a mask stage of an exposure apparatus and exposure-transferred on a resist film on a semiconductor device, a circuit pattern to be finally formed on the semiconductor device is formed at a high precision. Therefore, the transfer mask 200 manufactured by the method of manufacturing the transfer mask of Example 4 is considered as resulting in a transfer mask having high transfer precision.

### Example 5

### [Manufacture of Mask Blank]

The mask blank of Example 5 was manufactured by the same procedure as the mask blank 100 of Example 1, except for the light shielding film which was made as below.

The method of forming the light shielding film of Example 5 is as described below.

The transparent substrate 1 was placed in a single-wafer RF sputtering apparatus, and by reactive sputtering by RF power source (RF sputtering) using a silicon (Si) target, with mixed gas of argon (Ar), nitrogen (N₂), and helium (He) (flow ratio Ar:N₂:He=30:7.0:100) as sputtering gas, a light shielding film 2 made of silicon and nitrogen was formed on the transparent substrate 1 with a thickness of 52.1 nm. Electric power of RF power source during sputtering was 1500 W. While the single-wafer RF sputtering apparatus used in Example 5 has the same design specification as those used in Examples 1 to 4, the single-wafer RF sputtering apparatus is different from the apparatus of Examples 1 to 4.

Similar to Example 1, the transparent substrate 1 on which the light shielding film 2 was formed was subjected to heat treatment, and the optical density (OD) of the light shielding film 2 after the heat treatment was measured as 3.04. In view of this result, the mask blank of Example 5 has high light shielding performance that is necessary.

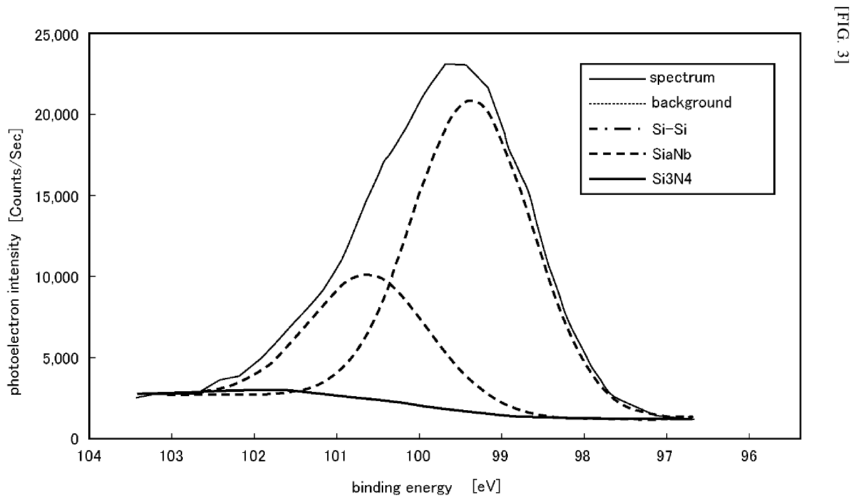

Similar to Example 1, another light shielding film was formed on a main surface of another transparent substrate under the same film forming condition as the light shielding film 2 of Example 5, and further subjected to heat treatment under the same condition. Next, through the same procedure as Example 1, the light shielding film of the other transparent substrate after the heat treatment of Example 5 was subjected to X-ray photoelectron spectroscopy. Further, among the Si₂p narrow spectrum of each depth of the obtained light shielding film, the ratios of the number of Si—Si bonds, SiₐN_{b} bonds, and Si₃N₄ bonds being present were calculated under the same procedure as Example 1 based on Si₂p narrow spectrum (see FIG. 3) of the predetermined depth corresponding to the inner region of the light shielding film. As a result, the ratio of the number of Si—Si bonds being present was 0.700, the ratio of the number of SiₐN_{b} bonds being present was 0.284, and the ratio of the number of Si₃N₄ bonds being present was 0.016. Namely, the condition of which the ratio calculated by dividing the number of Si₃N₄ bonds being present in the inner region by the total number of Si₃N₄ bonds, SiₐN_{b} bonds, and Si—Si bonds being present in the inner region is 0.04 or less, and the condition of which the ratio calculated by dividing the number of SiₐN_{b} bonds being present in the inner region by the total number of Si₃N₄ bonds, SiₐN_{b} bonds, and Si—Si bonds being present in the inner region is 0.1 or more were both satisfied (the former condition is satisfied by 0.016, and the latter condition is satisfied by 0.284).

Further, similar to Example 1, among the Si₂p narrow spectrum of each depth of the light shielding film obtained in Example 5, the ratios of the number of Si—Si bonds, SiₐN_{b} bonds, and Si₃N₄ bonds being present were calculated under the same procedure for each Si₂p narrow spectrum of the depth other than the predetermined depth corresponding to the inner region of the light shielding film. The ratios of the number of Si—Si bonds, SiₐN_{b} bonds, and Si₃N₄ bonds being present of any depth of the inner region showed similar tendency as the ratios of the number of Si—Si bonds, SiₐN_{b} bonds, and Si₃N₄ bonds being present of the predetermined depth. Further, all satisfied the two conditions regarding the ratio of the number present described above.

Thereafter, through the same procedure as Example 1, the mask blank 100 having a structure where the light shielding film 2 and the hard mask film 3 are stacked on the transparent substrate 1 was manufactured.

### [Manufacture of Transfer Mask]

Next, using the mask blank of Example 5, a transfer mask (binary mask) of Example 5 was manufactured through the same procedure as Example 1.

The manufactured transfer mask 200 of Example 5 was subjected to mask pattern inspection by a mask inspection apparatus, and the presence of a black defect was confirmed on the light shielding film pattern 2a of a location where a program defect was arranged. The black defect portion was subjected to an EB defect repair. The repair rate ratio of the light shielding film pattern 2a relative to the transparent substrate 1 was sufficiently high, and etching on the surface of the transparent substrate 1 could be minimized.

A simulation of a transfer image was made when an exposure transfer was made on a resist film on a semiconductor device using AIMS193 (manufactured by Carl Zeiss) at an exposure light of wavelength 193 nm on the transfer mask 200 of Example 5 after the EB defect repair. The simulated exposure transfer image was inspected, and the design specification was fully satisfied. Further, the transfer image of the portion subjected to the EB defect repair was at a comparable level to the transfer images of other regions. In view of the above result, it can be considered that when an EB defect repair was performed on a black defect portion of the light shielding film pattern 2a of the transfer mask 200 of Example 5, generation of surface roughness of the transparent substrate 1 can be suppressed and generation of a spontaneous etching in the light shielding film pattern 2a can also be suppressed. Further, it can be considered that when the transfer mask 200 of Example 5 after the EB defect repair was set on a mask stage of an exposure apparatus and exposure-transferred on a resist film on a semiconductor device, a circuit pattern to be finally formed on the semiconductor device is formed at a high precision. Therefore, the transfer mask 200 manufactured by the method of manufacturing the transfer mask of Example 5 is considered as resulting in a transfer mask having high transfer precision.

### Comparative Example 1

### [Manufacture of Mask Blank]

The mask blank of Comparative Example 1 was manufactured by the same procedure as the mask blank 100 of Example 1, except for the light shielding film which was made as below.

The method of forming the light shielding film of Comparative Example 1 is as described below.

A transparent substrate was placed in a single-wafer RF sputtering apparatus, and by reactive sputtering by RF power source (RF sputtering) using a silicon (Si) target, with mixed gas of argon (Ar), nitrogen (N₂), and helium (He) (flow ratio Ar:N₂:He=30:7.0:100) as sputtering gas, a light shielding film made of silicon and nitrogen was formed on the transparent substrate with a thickness of 52.8 nm. Electric power of RF power source during sputtering was 1500 W. The light shielding film of Comparative Example 1 was thus formed with the gas flow rate and sputtering output that are the same as Example 5. The single-wafer RF sputtering apparatus used in Comparative Example 1 is the same single-wafer RF sputtering apparatus used in Examples 1 to 4.

Similar to Example 1, the transparent substrate on which the light shielding film was formed was subjected to heat treatment, and the optical density (OD) of the light shielding film after the heat treatment was measured as 2.98. In view of this result, the mask blank of Comparative Example 1 has light shielding performance that is necessary.

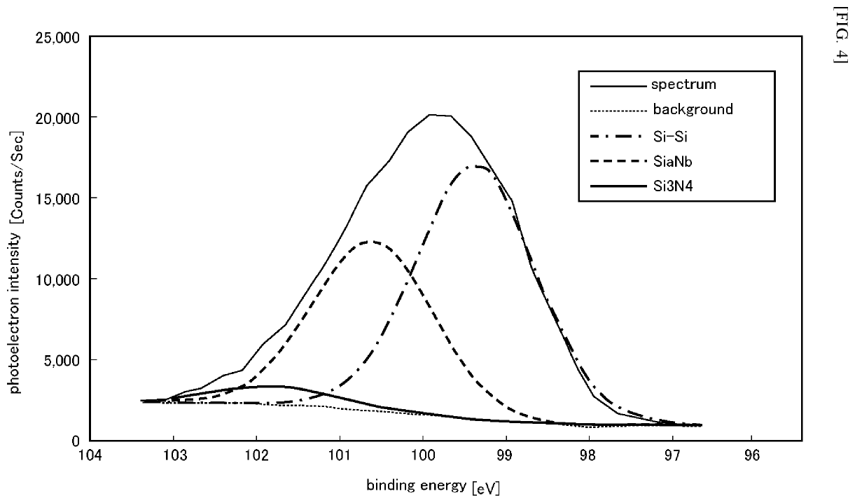

Similar to Example 1, another light shielding film was formed on a main surface of another transparent substrate under the same film forming condition as the light shielding film of Comparative Example 1, and further subjected to heat treatment under the same condition. Next, through the same procedure as Example 1, the light shielding film of the other transparent substrate after the heat treatment of Comparative Example 1 was subjected to X-ray photoelectron spectroscopy. Further, among the Si₂p narrow spectrum of each depth of the obtained light shielding film, the ratios of the number of Si—Si bonds, SiₐN_{b} bonds, and Si₃N₄ bonds being present were calculated under the same procedure as Example 1 based on Si₂p narrow spectrum (see FIG. 4) of the predetermined depth corresponding to the inner region of the light shielding film. As a result, the ratio of the number of Si—Si bonds being present was 0.574, the ratio of the number of SiₐN_{b} bonds being present was 0.382, and the ratio of the number of Si₃N₄ bonds being present was 0.044. Namely, the condition of which the ratio calculated by dividing the number of SiₐN_{b} bonds being present in the inner region by the total number of Si₃N₄ bonds, SiₐN_{b} bonds, and Si—Si bonds being present in the inner region is 0.1 or more was satisfied; however, the condition of which the ratio calculated by dividing the number of Si₃N₄ bonds being present in the inner region by the total number of Si₃N₄ bonds, SiₐN_{b} bonds, and Si—Si bonds being present in the inner region is 0.04 or less was not satisfied (the former condition was satisfied by 0.382, the latter condition was not satisfied by 0.044).

Further, similar to Example 1, among the Si₂p narrow spectrum of each depth of the light shielding film obtained in Comparative Example 1, the ratios of the number of Si—Si bonds, SiₐN_{b} bonds, and Si₃N₄ bonds being present were calculated under the same procedure for each Si₂p narrow spectrum of the depth other than the predetermined depth corresponding to the inner region of the light shielding film. The ratios of the number of Si—Si bonds, SiₐN_{b} bonds, and Si₃N₄ bonds being present of any depth of the inner region showed similar tendency as the ratios of the number of Si—Si bonds, SiₐN_{b} bonds, and Si₃N₄ bonds being present of the predetermined depth. Further, none satisfied the condition in which a number of Si₃N₄ bonds being present in the inner region divided by a total number of Si₃N₄ bonds, SiₐN_{b} bonds, and Si—Sis bond present is 0.04 or less.

In view of these results of the X-ray photoelectron spectroscopy, the average composition of the inner region of the light shielding film was found out to be Si:N:O=68.2:28.8:3.0 (atomic % ratio).

Thereafter, through the same procedure as Example 1, the mask blank having a structure where the light shielding film and the hard mask film are stacked on the transparent substrate was manufactured.

### [Manufacture of Transfer Mask]

Next, using the mask blank of Comparative Example 1, a transfer mask (binary mask) of Comparative Example 1 was manufactured through the same procedure as Example 1.

The manufactured transfer mask of Comparative Example 1 was subjected to mask pattern inspection by a mask inspection apparatus, and the presence of a black defect was confirmed on the light shielding film pattern of a location where a program defect was arranged. The black defect portion was subjected to an EB defect repair. The repair rate ratio of the light shielding film pattern relative to the transparent substrate was low, and an advancement of etching on the surface (surface roughness) of the transparent substrate was observed.

A simulation of a transfer image was made when an exposure transfer was made on a resist film on a semiconductor device using AIMS193 (manufactured by Carl Zeiss) at an exposure light of wavelength 193 nm on the transfer mask of Comparative Example 1 after the EB defect repair. The simulated exposure transfer image was inspected, resulting in CD reduction in the light shielding film pattern also in portions other than those subjected to the EB defect repair, which is considered as caused by slow etching rate in dry etching in forming a pattern in the light shielding film. Further, the transfer image of the portion subjected to the EB defect repair was at a level where a transfer defect will occur caused by an influence of surface roughness of the transparent substrate, etc. It can be understood from this result that when the transfer mask of Comparative Example 1 after an EB defect repair was set on a mask stage of an exposure apparatus and exposure-transferred on a resist film on a semiconductor device, generation of short-circuit or disconnection of circuit pattern is expected on a circuit pattern to be finally formed on the semiconductor device.

### Comparative Example 2

### [Manufacture of Mask Blank]

The mask blank of Comparative Example 2 was manufactured by the same procedure as the mask blank 100 of Example 1, except for the light shielding film which was made as below.

The method of forming the light shielding film of Comparative Example 2 is as described below.

A transparent substrate was placed in a single-wafer RF sputtering apparatus, and by reactive sputtering by RF power source (RF sputtering) using a silicon (Si) target, with mixed gas of argon (Ar), nitrogen (N₂), and helium (He) (flow ratio Ar:N₂:He=30:2.0:100) as sputtering gas, a light shielding film made of silicon and nitrogen was formed on the transparent substrate with a thickness of 48.0 nm. Electric power of RF power source during sputtering was 1500 W. Thus, the single-wafer RF sputtering apparatus used in Comparative Example 2 is the same single-wafer RF sputtering apparatus used in Examples 1 to 4 and Comparative Example 1.

Similar to Example 1, the transparent substrate on which the light shielding film was formed was subjected to heat treatment, and the optical density (OD) of the light shielding film after the heat treatment was measured as 3.04. In view of this result, the mask blank of Comparative Example 2 has high light shielding performance that is necessary.

Similar to Example 1, another light shielding film was formed on a main surface of another transparent substrate under the same film forming condition as the light shielding film of Comparative Example 2, and further subjected to heat treatment under the same condition. Next, through the same procedure as Example 1, the light shielding film of the other transparent substrate after the heat treatment of Comparative Example 2 was subjected to X-ray photoelectron spectroscopy. Further, among the Si₂p narrow spectrum of each depth of the obtained light shielding film, the ratios of the number of Si—Si bonds, SiₐN_{b} bonds, and Si₃N₄ bonds being present were calculated under the same procedure as Example 1 based on Si₂p narrow spectrum of the predetermined depth corresponding to the inner region of the light shielding film. As a result, the ratio of the number of Si—Si bonds being present was 0.978, the ratio of the number of SiₐN_{b} bonds being present was 0.022, and the ratio of the number of Si₃N₄ bonds being present was 0.000. Namely, the condition of which the ratio calculated by dividing the number of Si₃N₄ bonds being present in the inner region by the total number of Si₃N₄ bonds, SiₐN_{b} bonds, and Si—Si bonds being present in the inner region is 0.04 or less was satisfied; however, the condition of which the ratio calculated by dividing the number of SiₐN_{b} bonds being present in the inner region by the total number of Si₃N₄ bonds, SiₐN_{b} bonds, and Si—Si bonds being present in the inner region is 0.1 or more was not satisfied (the former condition was satisfied by 0.000, the latter condition was not satisfied by 0.022).

Further, similar to Example 1, among the Si₂p narrow spectrum of each depth of the light shielding film obtained in Comparative Example 2, the ratios of the number of Si—Si bonds, SiₐN_{b} bonds, and Si₃N₄ bonds being present were calculated under the same procedure for each Si₂p narrow spectrum of the depth other than the predetermined depth corresponding to the inner region of the light shielding film. The ratios of the number of Si—Si bonds, SiₐN_{b} bonds, and Si₃N₄ bonds being present of any depth of the inner region showed similar tendency as the ratios of the number of Si—Si bonds, SiₐN_{b} bonds, and Si₃N₄ bonds being present of the predetermined depth. Further, none of the portions satisfied the condition in which a ratio calculated by dividing a number of SiₐN_{b} bonds being present in the inner region by a total number of Si₃N₄ bonds, SiₐN_{b} bonds, and Si—Si bonds being present in the inner region is 0.1 or more.

Thereafter, through the same procedure as Example 1, the mask blank having a structure where the light shielding film and the hard mask film are stacked on the transparent substrate was manufactured.

### [Manufacture of Transfer Mask]

Next, using the mask blank of Comparative Example 2, a transfer mask (binary mask) of Comparative Example 2 was manufactured through the same procedure as Example 1.

The manufactured transfer mask of Comparative Example 2 was subjected to mask pattern inspection by a mask inspection apparatus, and the presence of a black defect was confirmed on the light shielding film pattern of a location where a program defect was arranged. The black defect portion was subjected to an EB defect repair, and an occurrence of an undercut was observed caused by the repair rate being too fast. Moreover, an advancement of an etching phenomenon due to the sidewall of the light shielding film pattern around the black defect portion being contacted by unexcited XeF₂ gas supplied upon EB defect repair, namely, a spontaneous etching, was observed.

A simulation of a transfer image was made when an exposure transfer was made on a resist film on a semiconductor device using AIMS193 (manufactured by Carl Zeiss) at an exposure light of wavelength 193 nm on the transfer mask of Comparative Example 2 after the EB defect repair. The simulated exposure transfer image was inspected, and surface roughness of the transparent substrate 1 at the portion subjected to the EB defect repair could not be observed. However, the transfer image around the portion subjected to the EB defect repair was at a level where a transfer defect will occur caused by an influence of a spontaneous etching, etc. It can be understood from this result that when the phase shift mask of Comparative Example 2 after an EB defect repair was set on a mask stage of an exposure apparatus and exposure-transferred on a resist film on a semiconductor device, generation of short-circuit or disconnection of circuit pattern is expected on a circuit pattern to be finally formed on the semiconductor device.

### DESCRIPTION OF REFERENCE NUMERALS

1 transparent substrate
2 light shielding film
2a light shielding film pattern
21 substrate vicinity region
22 inner region
23 surface layer region
3 hard mask film
3a hard mask pattern
4a resist pattern
100 mask blank
200 transfer mask (binary mask)

1. A mask blank comprising:
a transparent substrate; and
a light shielding film for forming a transfer pattern on the transparent substrate,
wherein the light shielding film is made of a material consisting of silicon and nitrogen, or is made of a material consisting of silicon, nitrogen, and one or more elements selected from the group consisting of metalloid elements and non-metallic elements, and
wherein the light shielding film comprises:
a vicinity region that includes an interface of the light shielding film with the transparent substrate,
a surface layer region that includes a surface of the light shielding film which faces away from the transparent substrate, and
an inner region between the vicinity region and the surface layer region, and
wherein a ratio of a number of Si₃N₄ bonds present in the inner region to a total number of Si₃N₄ bonds, Si—Si bonds, and SiₐN_{b} bonds present in the inner region (where a ratio of b to [a+b] is less than 4/7) is not more than 0.04, and
wherein a ratio of a number of SiₐN_{b} bonds present in the inner region to a total number of Si₃N₄ bonds, Si—Si bonds, and SiₐN_{b} bonds present in the inner region is not less than 0.1.

2. The mask blank according to claim 1, wherein an oxygen content of a region of the light shielding film that excludes the surface layer region is not more than 10 atom %.

3. The mask blank according to claim 1, wherein the surface layer region extends from the surface which faces away from the transparent substrate to a depth of 5 nm toward the transparent substrate.

4. The mask blank according to claim 1, wherein the vicinity region extends from the interface with the transparent substrate to a depth of 5 nm toward the surface layer region.

5. The mask blank according to claim 1, wherein the light shielding film is made of a material consisting of silicon, nitrogen, and a non-metallic element.

6. The mask blank according to claim 1, wherein an oxygen content of the surface layer region is higher than an oxygen content of a region of the light shielding film that excludes the surface layer region.

7. The mask blank according to claim 1, wherein an optical density of the light shielding film to exposure light of an ArF excimer laser is not less than 2.5.

8. The mask blank according to claim 1, wherein the light shielding film is provided in contact with a main surface of the transparent substrate.

9. A method of manufacturing a transfer mask using a mask blank that comprises a transparent substrate and a light shielding film on the transparent substrate, the method comprising forming a transfer pattern in the light shielding film by dry etching,
wherein the light shielding film is made of a material consisting of silicon and nitrogen, or is made of a material consisting of silicon, nitrogen, and one or more elements selected from the group consisting of metalloid elements and non-metallic elements, and
wherein the light shielding film comprises:
a vicinity region that includes an interface of the light shielding film with the transparent substrate,
a surface layer region that includes a surface of the light shielding film which faces away from the transparent substrate, and
an inner region between the vicinity region and the surface layer region, and
wherein a ratio of a number of Si₃N₄ bonds present in the inner region to a total number of Si₃N₄ bonds, Si—Si bonds, and SiₐN_{b} bonds present in the inner region (where a ratio of b to [a+b] is less than 4/7) is not more than 0.04, and
wherein a ratio of a number of SiₐN_{b} bonds present in the inner region to a total number of Si₃N₄ bonds, Si—Si bonds, and SiₐN_{b} bonds present in the inner region is not less than 0.1.

10. A method of manufacturing a semiconductor device comprising exposure-transferring a transfer pattern in a resist film on a semiconductor substrate using the transfer mask manufactured by the method of manufacturing a transfer mask according to claim 9.

11. The mask blank according to claim 2, wherein an oxygen content of the surface layer region is higher than an oxygen content of a region of the light shielding film that excludes the surface layer region.

12. The mask blank according to claim 2, wherein the surface layer region extends from the surface which faces away from the transparent substrate to a depth of 5 nm toward the transparent substrate, and
wherein the vicinity region extends from the interface with the transparent substrate to a depth of 5 nm toward the surface layer region, and
wherein an oxygen content of the surface layer region is higher than an oxygen content of a region of the light shielding film that excludes the surface layer region.

13. The mask blank according to claim 3, wherein the vicinity region extends from the interface with the transparent substrate to a depth of 5 nm toward the surface layer region.

14. A transfer mask comprising:
a transparent substrate; and
a light shielding film on the transparent substrate and having a transfer pattern,
wherein the light shielding film is made of a material consisting of silicon and nitrogen, or is made of a material consisting of silicon, nitrogen, and one or more elements selected from the group consisting of metalloid elements and non-metallic elements, and
wherein the light shielding film comprises:
a vicinity region that includes an interface of the light shielding film with the transparent substrate,
a surface layer region that includes a surface of the light shielding film which faces away from the transparent substrate, and
an inner region between the vicinity region and the surface layer region, and
wherein a ratio of a number of Si₃N₄ bonds present in the inner region to a total number of Si₃N₄ bonds, Si—Si bonds, and SiₐN_{b} bonds present in the inner region (where a ratio of b to [a+b] is less than 4/7) is not more than 0.04, and
wherein a ratio of a number of SiₐN_{b} bonds present in the inner region to a total number of Si₃N₄ bonds, Si—Si bonds, and SiₐN_{b} bonds present in the inner region is not less than 0.1.

15. The transfer mask according to claim 14, wherein an oxygen content of a region of the light shielding film that excludes the surface layer region is not more than 10 atom %, and
wherein an oxygen content of the surface layer region is higher than an oxygen content of the region of the light shielding film that excludes the surface layer region.

16. The transfer mask according to claim 15, wherein the surface layer region extends from the surface which faces away from the transparent substrate to a depth of 5 nm toward the transparent substrate, and
wherein the vicinity region extends from the interface with the transparent substrate to a depth of 5 nm toward the surface layer region.

17. The transfer mask according to claim 14, wherein the surface layer region extends from the surface which faces away from the transparent substrate to a depth of 5 nm toward the transparent substrate, and
wherein the vicinity region extends from the interface with the transparent substrate to a depth of 5 nm toward the surface layer region.

18. The transfer mask according to claim 14, wherein the light shielding film is made of a material consisting of silicon, nitrogen, and a non-metallic element.

19. The transfer mask according to claim 14, wherein an optical density of the light shielding film to exposure light of an ArF excimer laser is not less than 2.5.

20. The transfer mask according to claim 14, wherein the light shielding film is provided in contact with a main surface of the transparent substrate.
